(19) United States
(12) Patent Application Publication
(10) Pub. No.: US 2023/0216003 A1
(43) Pub. Date: Jul. 6, 2023

(54) DISPLAY DEVICE AND TILED DISPLAY DEVICE INCLUDING THE SAME

(71) Applicant: Samsung Display Co., LTD., Yongin-si (KR)

(72) Inventors: Kye Uk LEE, Seoul (KR); Jun Ki JEONG, Yongin-si (KR); Hyun Joon KIM, Hwaseong-si (KR); Jung Hwan HWANG, Seongnam-si (KR)

(21) Appl. No.: 17/900,742

(22) Filed: Aug. 31, 2022

(30) Foreign Application Priority Data
Dec. 30, 2021 (KR) 10-2021-0193114

(51) Int. Cl. H01L 33/62; G09F 9/302; G09F 9/33; H01L 33/42; H01L 33/38

(52) U.S. Cl. CPC H01L 33/62; G09F 9/3026; G09F 9/33; H01L 33/42; H01L 33/382

(57) ABSTRACT

A display device includes a substrate including a display area for displaying an image, and a non-display area around the display area, fan-out lines above the substrate, top antistatic layers along edges of a top surface above the substrate, and electrically connected to the fan-out lines, lead lines below the substrate, side connecting lines on sides of the substrate, and electrically connecting the fan-out lines and the lead lines, and bottom antistatic layers along edges of a bottom surface below the substrate, and electrically connected to the lead lines.

### CROSS-REFERENCE TO RELATED APPLICATION

This application claims priority to, and the benefit of, Korean Patent Application No. 10-2021-0193114 filed on Dec. 30, 2021, in the Korean Intellectual Property Office, the contents of which in its entirety are herein incorporated by reference.

### BACKGROUND

### 1. Field

The present disclosure relates to a display device, and to a tiled display device including the same.

### 2. Description of the Related Art

As the information society has developed, the demand for display devices for displaying images has diversified. For example, display devices have been applied to various electronic devices, such as smart phones, digital cameras, notebook computers, navigation systems, and smart televisions. Examples of display devices include flat panel display devices, such as a liquid crystal display (LCD) device, a field emission display (FED) device, or an organic light-emitting diode (OLED) display device. A light-emitting display device, which is a type of flat panel display device, includes light-emitting elements capable of emitting light, and can thus display an image without a requirement of a backlight unit for providing light to a display panel.

When a large-size display device is fabricated, the defect rate of light-emitting elements may increase due to an increase in the number of pixels, and the productivity or reliability of the display device may decrease. To address these problems, a tiled display device with a large screen may be implemented by connecting multiple display devices having a relatively small size. The tiled display device may include seams (or boundary portions) between the multiple display devices due to the presence of the non-display areas or bezels of the multiple display devices. However, when an image is being displayed on the entire screen of the tiled display device, the seams may cause a sense of discontinuity, adversely affecting the sense of immersion of the image.

### SUMMARY

Aspects of the present disclosure provide a display device capable of quickly discharging static electricity introduced from thereabove or from therebelow, and a tiled display device including the display device.

Aspects of the present disclosure also provide a display device capable of eliminating the sense of discontinuity between multiple display devices, and capable of enhancing the sense of immersion of an image by reducing or preventing visibility of boundary portions or non-display areas between the multiple display devices, and a tiled display device including the display device.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the disclosure, a display device includes a substrate including a display area for displaying an image, and a non-display area around the display area, fan-out lines above the substrate, top antistatic layers along edges of a top surface above the substrate, and electrically connected to the fan-out lines, lead lines below the substrate, side connecting lines on sides of the substrate, and electrically connecting the fan-out lines and the lead lines, and bottom antistatic layers along edges of a bottom surface below the substrate, and electrically connected to the lead lines.

The display device may further include pixel electrodes in the display area, and configured to receive driving currents, wherein the top antistatic layers and the pixel electrodes include a same material in a same layer.

The display device may further include a passivation layer covering edges of the pixel electrodes, and covering edges of the top antistatic layers such that top surfaces of top antistatic layers are exposed by the passivation layer.

The top antistatic layers may include at least one of indium tin oxide (ITO), indium zinc oxide (IZO), or indium tin zinc oxide (ITZO).

The display device may further include pad units in the non-display area, and separated from the top antistatic layers in plan view.

Some of the lead lines may be separated from the bottom antistatic layers in plan view, and extend from the display area to edges of the non-display area.

The fan-out lines may be electrically connected to a low-potential electrode or a common voltage line.

The display device may further include contact electrodes below the substrate, and electrically connected to the lead lines, and flexible films electrically connected to the contact electrodes, wherein the bottom antistatic layers and the contact electrodes include a same material.

The side connecting lines might not be in direct contact with the top antistatic layers or the bottom antistatic layers.

The display device may further include pixels including at least one light-emitting element, and antistatic circuits between the top antistatic layers and the pixels.

The display device may further include transistors above the substrate, connecting electrodes above, and electrically connected to, the transistors, anode connecting lines above, and electrically connected to, the connecting electrodes, anode connecting electrodes above, and electrically connected to, the anode connecting lines, and pixel electrodes above, and electrically connected to, the anode connecting electrodes.

The top antistatic layers and the anode connecting electrodes may include a same material in a same layer.

The top antistatic layers and the anode connecting lines may include a same material in a same layer.

The top antistatic layers and the connecting electrodes may include a same material in a same layer.

According to one or more embodiments of the disclosure, a display device includes a substrate including a display area for displaying an image, and a non-display area around the display area, fan-out lines above the substrate, top antistatic layers along edges of a top surface above the substrate, and electrically connected to the fan-out lines, side connecting lines on sides of the substrate, and electrically connecting the fan-out lines and lead lines, and bottom antistatic layers along edges of a bottom surface below the substrate, and electrically connected to the fan-out lines, wherein the side connecting lines are not in direct contact with the top antistatic layers or the bottom antistatic layers.

The display device may further include flexible films below the substrate, and lead lines electrically connected between the flexible films and the side connecting lines.

The bottom antistatic layers may be electrically connected to the fan-out lines through the lead lines and the side connecting lines.

The display device may further include pad units in the non-display area, and separated from the top antistatic layers in plan view.

Some of the lead lines may be separated from the bottom antistatic layers in plan view, and may extend from the display area to edges of the non-display area.

According to one or more embodiments of the disclosure, a tiled display device includes display devices including a substrate including a display area for displaying an image, and a non-display area around the display area, fan-out lines above the substrate, top antistatic layers along edges of a top surface above the substrate, and electrically connected to the fan-out lines, lead lines below the substrate, side connecting lines on sides of the substrate, and electrically connecting the fan-out lines and the lead lines, and bottom antistatic layers along edges of a bottom surface below the substrate, and electrically connected to the lead lines, and a bonding area between the display devices.

According to the aforementioned and other embodiments of the present disclosure, as a display device includes top antistatic layers, static electricity that may be introduced from above the display device can be discharged so that damage to a thin-film transistor (TFT) layer and a light-emitting element layer can be reduced or prevented. Also, as the display device includes bottom antistatic layers, static electricity that may be introduced from below the display device can be discharged so that damage to lead lines, flexible films, and display drivers can be reduced or prevented.

Also, as the distance between a plurality of display devices of a tiled display device can be reduced or minimized, the bonding area between the plurality of display devices can be reduced or prevented from becoming recognizable to a user, and the sense of discontinuity between the plurality of display devices can be overcome, thereby improving the degree of immersion of an image displayed by the tiled display device.

It should be noted that the aspects of the present disclosure are not limited to those described above, and other aspects of the present disclosure will be apparent from the following description.

### BRIEF DESCRIPTION OF THE DRAWINGS

The above and other aspects of the present disclosure will become more apparent by describing in detail embodiments thereof with reference to the attached drawings, in which:

FIG. 1 is a plan view of a tiled display device according to one or more embodiments of the present disclosure;

FIG. 2 is a plan view of a display device according to one or more embodiments of the present disclosure;

FIG. 3 is a bottom view of the display device of FIG. 2;

FIGS. 4 and 5 illustrate a pad unit, antistatic circuits, and a first fan-out line in the display device of FIG. 2;

FIG. 6 is a cross-sectional view taken along the line I-I′ of FIG. 2, according to one or more embodiments of the present disclosure;

FIG. 7 is a cross-sectional view taken along the line II-II′ of FIG. 2, according to one or more embodiments of the present disclosure;

FIG. 8 is a cross-sectional view taken along the line II-II′ of FIG. 2, according to one or more embodiments of the present disclosure;

FIG. 9 is a cross-sectional view taken along the line II-II′ of FIG. 2, according to one or more embodiments of the present disclosure;

FIG. 10 is a cross-sectional view taken along the line II-II′ of FIG. 2, according to one or more embodiments of the present disclosure;

FIG. 11 illustrates how stages and gate lines are connected in the display device of FIG. 2; and

FIG. 12 is a circuit diagram of a pixel of the display device of FIG. 2.

### DETAILED DESCRIPTION

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods employing one or more of the disclosure disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of one or more embodiments may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When one or more embodiments may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation, not as terms of degree, and thus are utilized to account for inherent deviations in measured, calculated, and/or provided values that would be recognized by one of ordinary skill in the art.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or overly formal sense, unless clearly so defined herein.

Hereinafter, detailed embodiments of the present disclosure will be described with reference to the accompanying drawings.

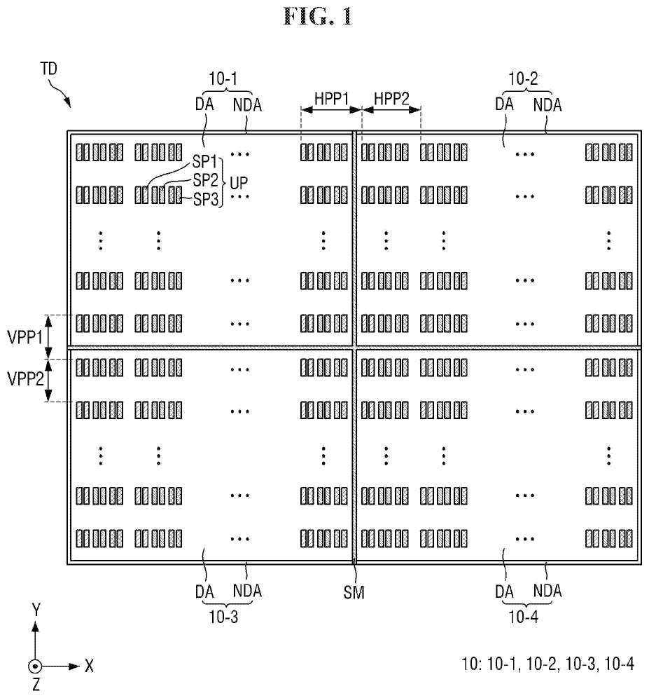

FIG. 1 is a plan view of a tiled display device according to one or more embodiments of the present disclosure.

Referring to FIG. 1, a tiled display device TD may include a plurality of display devices 10. The display devices 10 may be arranged in a lattice pattern, but the present disclosure is not limited thereto. The display devices 10 may be connected to one another in a first direction (or an X-axis direction) and/or a second direction (or a Y-axis direction), and the tiled display device TD may have a corresponding shape. For example, the display devices 10 may all have the same size, but the present disclosure is not limited thereto. In another example, the display devices 10 may have different sizes.

The tiled display device TD may include first through fourth display devices 10-1 through 10-4. The number of display devices 10 included in the tiled display device TD and how the display devices 10 are coupled to one another are not particularly limited. The number of display devices 10 included in the tiled display device TD may be determined by the size of the display devices 10 and the size of the tiled display device TD.

The display devices 10 may have a rectangular shape with a pair of long sides and a pair of short sides. The display devices 10 may be arranged by connecting respective ones of the long sides or the short sides of each of the display devices 10. Some of the display devices 10 may be arranged along the edges of the tiled display device TD to form the sides of the tiled display device TD. Some of the display devices 10 may be arranged at the corners of the tiled display device TD to form each pair of adjacent sides of the tiled display device TD. In one or more other embodiments, some of the display devices 10 may be located in the middle of the tiled display device TD, and may be surrounded by other display devices 10.

Each of the display devices 10 may include a display area DA and a non-display area NDA. The display area DA may include a plurality of unit pixels UP, and may display an image. Each of the unit pixels UP may include first pixels SP1, second pixels SP2, and third pixels SP3. Each of the first pixels SP1, the second pixels SP2, and the third pixels SP3 may include organic light-emitting diodes (OLEDs) including organic light-emitting layers, quantum-dot light-emitting diodes (LEDs) including quantum-dot light-emitting layers, inorganic LEDs including an inorganic semiconductor, or microLEDs. Each of the first pixels SP1, the second pixels SP2, and the third pixels SP3 will hereinafter be described as including microLEDs, but the present disclosure is not limited thereto. The non-display area NDA may be located around the display area DA to surround the display area DA in plan view, and may not display an image.

Each of the display devices 10 may include a plurality of unit pixels UP, which are arranged in multiple rows and columns. Each of the unit pixels UP may include first pixels SP1, second pixels SP2, and third pixels SP3. Each of the first pixels SP1, the second pixels SP2, and the third pixels SP3 may include an emission area (or an opening area) defined by a pixel-defining film or by a bank, and may emit light having a corresponding peak wavelength through the emission area. Here, the emission area may be an area that outputs light generated by light-emitting elements to the outside of each of the display devices 10. The first pixels SP1 may emit first-color light, the second pixels SP2 may emit second-color light, and the third pixels SP3 may emit third-color light. For example, the first-color light may be red light having a peak wavelength of about 610 nm to about 650 nm, the second-color light may be green light having a peak wavelength of about 510 nm to about 550 nm, and the third-color light may be blue light having a peak wavelength of about 440 nm to about 480 nm. However, the present disclosure is not limited to this example.

The first pixels SP1, the second pixels SP2, and the third pixels SP3 may be repeatedly arranged along the first direction (or the X-axis direction) of the display area DA. For example, the emission areas of the first pixels SP1, the emission areas of the second pixels SP2, and the emission areas of the third pixels SP3 may all have substantially the same size, but the present disclosure is not limited thereto. In another example, the emission areas of the first pixels SP1, the emission areas of the second pixels SP2, and the emission areas of the third pixels SP3 may have different respective sizes, but the present disclosure is not limited thereto.

The tiled display device TD may generally have a flat shape, but the present disclosure is not limited thereto. The tiled display device TD may have a stereoscopic shape (e.g., non-flat shape), and may thus provide a sense of depth to a user. For example, in a case where the tiled display device TD has a stereoscopic shape, at least some of the display devices 10 may have a curved shape. In another example, the display devices 10 may all have a flat shape, and may be connected to one another at an angle (e.g., a predetermined angle), so that the tiled display device TD may have a stereoscopic shape.

The tiled display device TD may include a bonding area SM, which is located between a plurality of display areas DA. The tiled display device TD may be obtained by connecting the non-display areas NDA of the display devices 10. The display devices 10 may be connected to one another via a bonding member or an adhesive member located in the bonding area SM. The bonding area SM may not include pad units or flexible films attached to pad units. The distance between the display areas DA of the display devices 10 may be so close that the bonding area SM may become almost invisible to the user. For example, a first horizontal pixel pitch HPP1 between pixels (SP1, SP2, and SP3) of the first display device 10-1 and pixels (SP1, SP2, and SP3) of the second display device 10-2 may be substantially the same as a second horizontal pixel pitch HPP2 between the pixels (SP1, SP2, and SP3) of the second display device 10-2, and a first vertical pixel pitch VPP1 between pixels (SP1, SP2, and SP3) of the first display device 10-1 and pixels (SP1, SP2, and SP3) of the third display device 10-3 may be substantially the same as a second vertical pixel pitch VPP2 between the pixels (SP1, SP2, and SP3) of the third display device 10-3. Accordingly, the tiled display device TD can overcome the sense of discontinuity between the display devices 10, and may improve the degree of immersion of an image by reducing or preventing recognizability of the bonding area SM by the user.

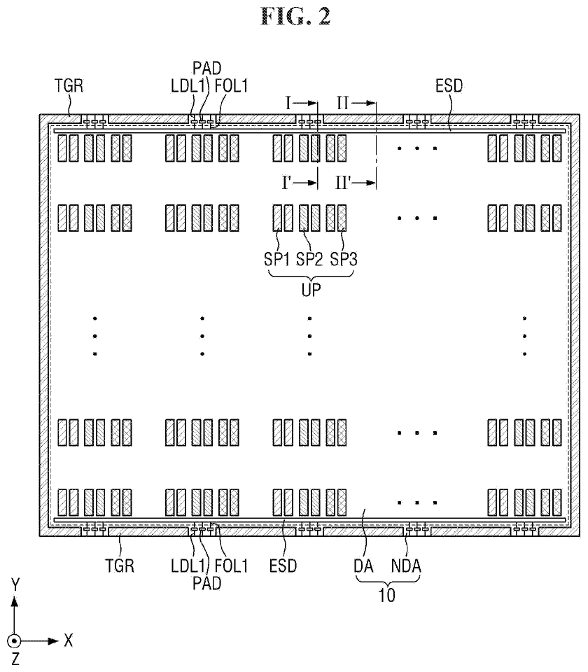

FIG. 2 is a plan view of a display device according to one or more embodiments of the present disclosure.

Referring to FIG. 2, a display device 10 may include the display area DA and the non-display area NDA. The display area DA may include the unit pixels UP and antistatic circuits ESD.

The unit pixels UP may be arranged to have a uniform pixel pitch. The unit pixels UP may be arranged in rows and columns. The unit pixels UP may include first pixels SP1, second pixels SP2, and third pixels SP3. The first pixels SP1, the second pixels SP2, and the third pixels SP3 may correspond to light-emitting elements exposed by opening areas. For example, each of the first pixels SP1, the second pixels SP2, and the third pixels SP3 may include two light-emitting elements. In this example, each of the first pixels SP1, the second pixels SP2, and the third pixels SP3 may include a main light-emitting element and a repair light-emitting element, but the present disclosure is not limited thereto. In another example, each of the first pixels SP1, the second pixels SP2, and the third pixels SP3 may include three or more light-emitting elements. Thus, the first pixels SP1, the second pixels SP2, and the third pixels SP3 may emit light corresponding to their gray levels.

The antistatic circuits ESD may be located along the right and left edges, or along the upper and lower edges, of the display area DA, but the present disclosure is not limited thereto. The antistatic circuits ESD may be located adjacent to first fan-out lines FOL1, which are electrically connected to flexible films. For example, in a case where the first fan-out lines FOL1 are located along the upper and lower edges of the display area DA, the antistatic circuits ESD may also be located along the upper and lower edges of the display area DA. The antistatic circuits ESD may reduce or prevent the likelihood of static electricity being introduced into the display area DA from the outside through the first fan-out lines FOL1 by dissipating the static electricity.

The non-display area NDA may include first lead lines LDL1, the pad units PAD, the first fan-out lines FOL1, and top antistatic layers TGR.

The first lead lines LDL1 may be located along edges of the non-display area NDA. The first lead lines LDL1 may be located along upper and lower edges of the non-display area NDA, but the present disclosure is not limited thereto. The first lead lines LDL1 may be located between the top antistatic layers TGR (e.g., in plan view). The first lead lines LDL1 may not overlap with the top antistatic layers TGR in a third direction (e.g., a Z-axis direction, or a thickness direction). That is, the first lead lines LDL1 may be separated from the top antistatic layers TGR in plan view. The first lead lines LDL1 may be electrically connected to the flexible films through side connecting lines, which are located on sides of the display device 10, and through second lead lines, which are located in a lower part of the display device 10. The first lead lines LDL1 may provide voltages or signals from the flexible films to the pad units PAD and the first fan-out lines FOL1.

The pad units PAD may be located along edges of the non-display area NDA. The pad units PAD may be located along the upper and lower edges of the non-display area NDA, but the present disclosure is not limited thereto. The pad units PAD may be located between the top antistatic layers TGR (e.g., in plan view). The pad units PAD may not overlap with the top antistatic layers TGR in the third direction (e.g., the Z-axis direction, or the thickness direction). That is, the pad units PAD may be separated from the top antistatic layers TGR in plan view. The pad units PAD may be electrically connected to the flexible films through the first lead lines LDL1, the side connecting lines, and the second lead lines.

The first fan-out lines FOL1 may extend from the non-display area NDA to the display area DA. The first fan-out lines FOL1 may be located along the upper and lower edges of the display device 10, but the present disclosure is not limited thereto. The first fan-out lines FOL1 may not overlap with the top antistatic layers TGR in the third direction (e.g., the Z-axis direction, or the thickness direction). That is, the first fan-out lines FOL1 may be separated from the top antistatic layers TGR in plan view. The first fan-out lines FOL1 may be electrically connected to the flexible films through the first lead lines LDL1, the side connecting lines, and the second lead lines. The first fan-out lines FOL1 may provide voltages or signals from the first lead lines LDL1 to the display area DA. For example, the first fan-out lines FOL1 may be electrically connected to data lines, clock lines, or voltage lines in the display area DA.

The top antistatic layers TGR may be located along the edges of the top surface of the display device 10 or along the edges of the top of a substrate to surround, or partially surround, the display area DA (e.g., in plan view). The top antistatic layers TGR may be located along parts of the upper and lower edges of the non-display area NDA and along the left and right edges of the non-display area NDA. As the top antistatic layers TGR are not located along parts of the upper and lower edges of the non-display area NDA, the top antistatic layers TGR may not overlap with the pad units PAD and the first fan-out lines FOL1 in the third direction (e.g., the Z-axis direction, or the thickness direction). That is, the top antistatic layers TGR may be separated from the pad units PAD and the first fan-out lines FOL1 in plan view. The top antistatic layers TGR may be guard rings capable of reducing or preventing static electricity, but the present disclosure is not limited thereto. The top antistatic layers TGR may be electrically connected to a low-potential electrode or a common voltage line, and thus may be able to suitably discharge static electricity. Here, the low-potential electrode or the common voltage line may receive a low-potential voltage or a common voltage. As the top antistatic layers TGR are located along the edges of the top surface of the display device 10, static electricity that may be introduced during the cutting or grinding of the display device 10 can be discharged, and thus the likelihood of static electricity being introduced into the display area DA may be reduced or prevented. The top antistatic layers TGR can suitably discharge static electricity that may be introduced from above the display device 10.

For example, the top antistatic layers TGR may include a transparent conductive material, such as indium tin oxide (ITO), indium zinc oxide (IZO), or indium tin zinc oxide (ITZO). In another example, the top antistatic layers TGR may have a stack structure, such as ITO/silver (Ag)/ITO, ITO/Ag/IZO, or ITO/Ag/ITZO/IZO. In yet another example, the top antistatic layers TGR may include at least one of molybdenum (Mo), aluminum (Al), chromium (Cr), gold (Au), titanium (Ti), nickel (Ni), neodymium (Nd), and copper (Cu).

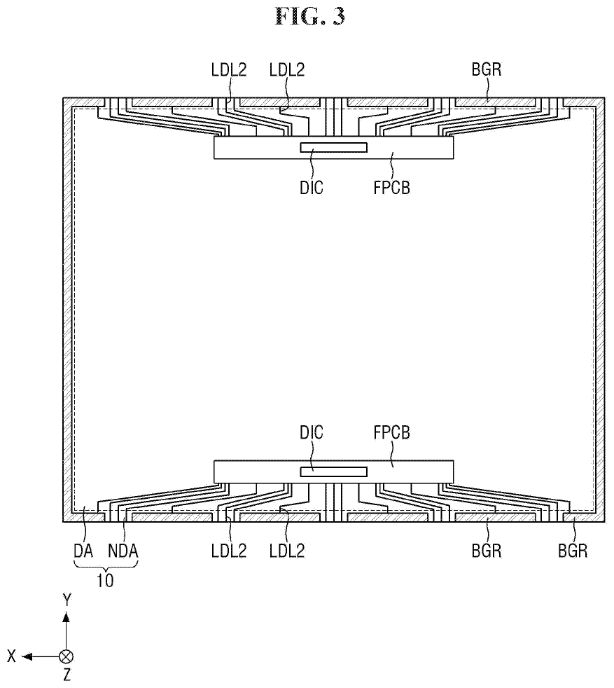

FIG. 3 is a bottom view of the display device of FIG. 2.

Referring to FIG. 3, the display device 10 may include the display area DA and the non-display area NDA. The display area DA may include flexible films FPCB, display drivers DIC, and second lead lines LDL2.

The flexible films FPCB may be located on the bottom surface of the display device 10. The flexible films FPCB may be attached to the bottom surface of the display device 10 through an adhesive member or an anisotropic conductive film. The flexible films FPCB may provide voltages or signals to the first fan-out lines FOL1, which are located at the top of the substrate, through the second lead lines LDL2, the side connecting lines, and the first lead lines LDL1. For example, an upper flexible film FPCB in an upper part of display area DA may provide voltages or signals to an upper first fan-out line FOL1 located at the upper side of the display area DA, and a lower flexible film FPCB in a lower part of display area DA may provide voltages or signals to a lower first fan-out line FOL1 located at the lower side of the display area DA. The flexible films FPCB may transmit signals from the display drivers DIC to the display device 10.

The display drivers DIC may output signals and voltages for driving the first pixels SP1, the second pixels SP2, and the third pixels SP3. The display drivers DIC may provide data voltages to the data lines. The data voltages may be provided to the first pixels SP1, the second pixels SP2, and the third pixels SP3, and may determine the luminances of the first pixels SP1, the second pixels SP2, and the third pixels SP3. The display drivers DIC may provide power supply voltages to the power supply lines, and gate control signals to gate drivers. For example, the display drivers DIC may be formed as integrated circuits (IC) and then may be mounted on the flexible films FPCB in a chip-on-film (COF) or tape carrier package (TCP) manner, but the present disclosure is not limited thereto.

The second lead lines LDL2 may extend from the flexible films FPCB in the display area DA to the edges of the non-display area NDA. The second lead lines LDL2 may be located on the upper and lower edges of the bottom surface of the display device 10, but the present disclosure is not limited thereto. The second lead lines LDL2 may be located between bottom antistatic layers BGR (e.g., in plan view). The second lead lines LDL2 may not overlap with the bottom antistatic layers BGR in the third direction (e.g., the Z-axis direction, or the thickness direction). That is, the second lead lines LDL2 may be separated from the bottom antistatic layers BGR in plan view. The second lead lines LDL2 may provide voltages or signals from the flexible films FPCB to the first fan-out lines FOL1 through the side connecting lines and the first lead lines LDL1. For example, an upper second lead line LDL2 located in the upper part of the display area DA may be electrically connected to the upper first fan-out line FOL1, and a lower second lead line LDL2 located in the lower part of the display area DA may be electrically connected to the lower first fan-out line FOL1.

The bottom antistatic layers BGR may be located along the edges of the bottom surface of the display device 10, or along the edges of the bottom of the substrate, to surround, or partially surround, the display area DA (e.g., in plan view). The bottom antistatic layers BGR may be located along parts of the upper and lower edges of the non-display area NDA, and along the left and right edges of the non-display area NDA. As the bottom antistatic layers BGR are not located along respective portions of the upper and lower edges of the non-display area NDA, the bottom antistatic layers BGR may not overlap with the second lead lines LDL2 in the third direction (e.g., the Z-axis direction, or the thickness direction). That is, the bottom antistatic layers BGR may be separated from the second lead lines LDL2 in plan view. The bottom antistatic layers BGR may be guard rings capable of reducing or preventing static electricity, but the present disclosure is not limited thereto. The bottom antistatic layers BGR may be electrically connected to a low-potential electrode or a common voltage line, and thus may be able to suitably discharge static electricity. As the bottom antistatic layers BGR are located along the edges of the bottom surface of the display device 10, static electricity that may be introduced during the cutting or grinding of the display device 10 can be discharged, and thus a likelihood of static electricity being introduced into the display area DA can be reduced or prevented. The bottom antistatic layers BGR can suitably discharge static electricity that may be introduced from below the display device 10.

For example, the bottom antistatic layers BGR may include a transparent conductive material, such as ITO, IZO, or ITZO. In another example, the bottom antistatic layers BGR may have a stack structure, such as ITO/Ag/ITO, ITO/Ag/IZO, or ITO/Ag/ITZO/IZO. In yet another example, the bottom antistatic layers BGR may include at least one of Mo, Al, Cr, Au, Ti, Ni, Nd, and Cu.

As the display device 10 includes the flexible films FPCB and the display drivers DIC at the bottom thereof, the size of the non-display area NDA can be reduced or minimized, and the pixel pitch between the display device 10 and other neighboring display devices 10 can be designed to be the same as the pixel pitch within the display device 10. As the display device 10 includes the top antistatic layers TGR, static electricity that may be introduced from above the display device 10 can be discharged so that damage to a thin-film transistor (TFT) layer and a light-emitting element layer can be reduced or prevented. As the display device 10 includes the bottom antistatic layers BGR, static electricity, which may be introduced from below the display device 10, can be discharged so that damage to the second lead lines LDL2, the flexible films FPCB, and the display drivers DIC can be reduced or prevented.

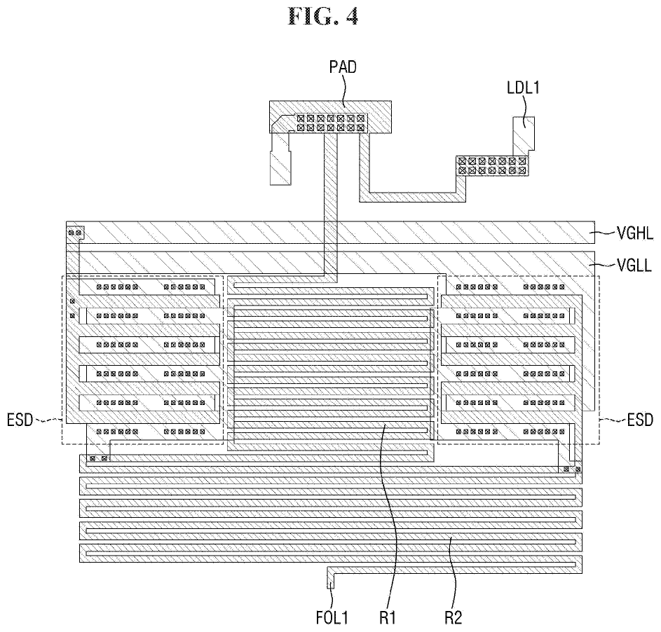

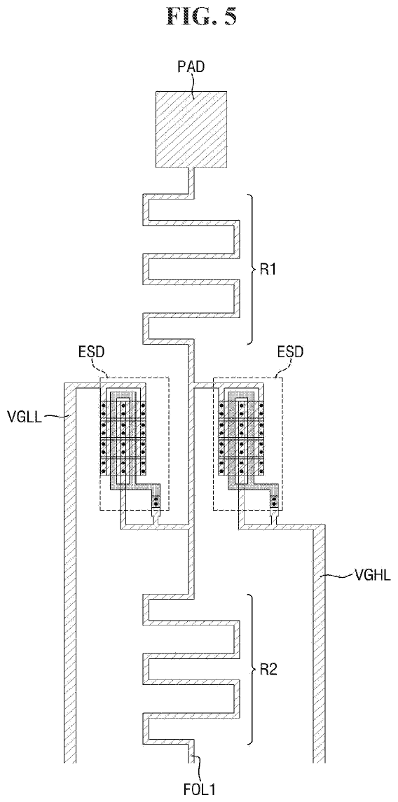

FIGS. 4 and 5 illustrate a pad unit, anti-static circuits, and a first fan-out line in the display device of FIG. 2.

Referring to FIGS. 4 and 5, each of the first fan-out lines FOL1, which are connected to the pad units PAD, may include first and second line resistors R1 and R2. The first and second line resistors R1 and R2 may be formed as zigzag patterns. The lengths of the first and second line resistors R1 and R2 may vary depending on the location of a corresponding first fan-out line FOL1. Thus, the first fan-out lines FOL1 of the display device 10 may have substantially the same length, and may thus have substantially the same resistance.

The antistatic circuits ESD may be located adjacent to the first fan-out lines FOL1. Some of the antistatic circuits ESD may be connected between a first fan-out line FOL1 and a gate-high voltage line VGHL, and some of the antistatic circuits ESD may be connected to a gate-low voltage line VGLL. The antistatic circuits ESD may be connected between the first line resistors R1 and the second line resistors R2 of the first fan-out lines FOL1, but the present disclosure is not limited thereto. Accordingly, the antistatic circuits ESD can reduce or prevent the likelihood of static electricity, which is introduced from the outside, being introduced into the display area DA through the first fan-out lines FOL1 by dissipating the static electricity.

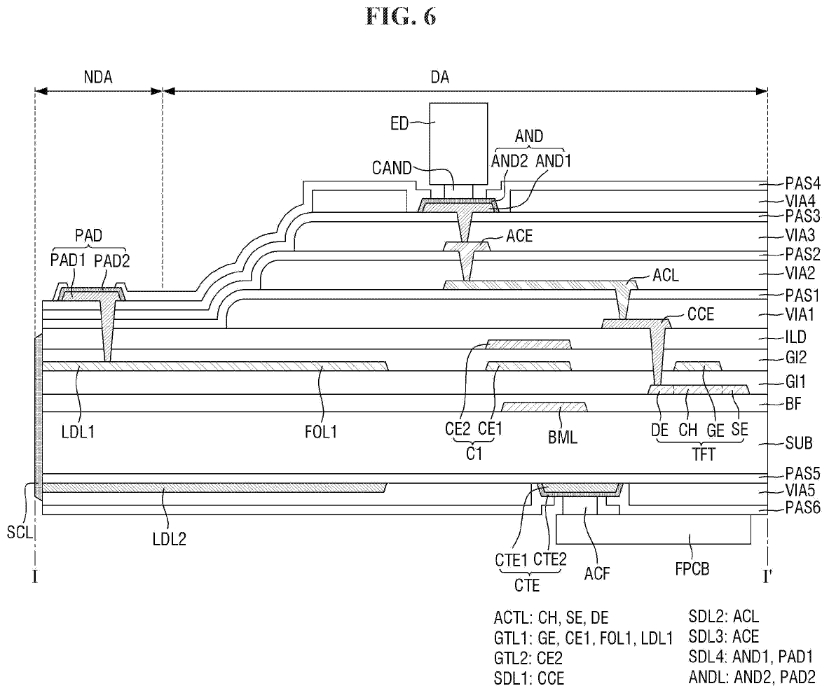

FIG. 6 is a cross-sectional view taken along the line I-I′ of FIG. 2.

Referring to FIG. 6, the display device 10 may include a substrate SUB, a light-blocking layer BML, a buffer layer BF, an active layer ACTL, a first gate insulating film GI1, a first gate layer GTL1, a second gate insulating film GI2, a second gate layer GTL2, an interlayer insulating film ILD, a first source metal layer SDL1, a first via layer VIA1, a first passivation layer PAS1, a second source metal layer SDL2, a second via layer VIA2, a second passivation layer PAS2, a third source metal layer SDL3, a third via layer VIA3, a third passivation layer PAS3, a fourth source metal layer SDL4, an anode layer ANDL, a fourth via layer VIA4, a fourth passivation layer PAS4, a fifth passivation layer PAS5, a contact electrode CTE, a second lead line LDL2, a side connecting line SCL, a fifth via layer VIAS, a sixth passivation layer PAS6, and a flexible film FPCB.

The substrate SUB may support the display device 10. The substrate SUB may be a base substrate or a base member. The substrate SUB may be a flexible substrate that is bendable, foldable, or rollable. For example, the substrate SUB may include an insulating material, such as a polymer resin, for example, polyimide, but the present disclosure is not limited thereto. In another example, the substrate SUB may be a rigid substrate including a glass material.

The light-blocking layer BML may be located on the substrate SUB. The light-blocking layer BML may block light incident upon a thin film transistor TFT and a pixel electrode AND. The light-blocking layer BML may include at least one of Mo, Al, Cr, Au, Ti, Ni, Nd, and Cu.

The buffer layer BF may be located on the substrate SUB. The buffer layer BF may include an inorganic material capable of reducing or preventing the infiltration of air or moisture. The buffer layer BF may include a plurality of inorganic films that are alternately stacked. For example, the buffer layer BF may be a multilayer film in which at least one inorganic film selected from among a silicon nitride layer, a silicon oxynitride layer, a silicon oxide layer, a titanium oxide layer, and an aluminum oxide layer is alternately stacked.

The active layer ACTL may be located on the buffer layer BF. The active layer ACTL may include a channel CH, a source electrode SE, and a drain electrode DE of the transistor TFT. Here, the transistor TFT may be part of a pixel circuit. The source electrode SE and the drain electrode DE may be formed into conductors by thermally treating the active layer ACTL. For example, the active layer ACTL may include polycrystalline silicon, monocrystalline silicon, low-temperature polycrystalline silicon, amorphous silicon, or an oxide semiconductor. The active layer ACTL may include first and second active layers, which are on different layers. The first active layer may include polycrystalline silicon, monocrystalline silicon, low-temperature polycrystalline silicon, or amorphous silicon, and the second active layer may include an oxide semiconductor.

The first gate insulating film GI1 may be located on the active layer ACTL. The first gate insulating film GI1 may insulate a gate electrode GE and the channel CH of the transistor TFT. The first gate insulating film GI1 may include an inorganic film. For example, the first gate insulating film GI1 may include one of a silicon nitride layer, a silicon oxynitride layer, a silicon oxide layer, a titanium oxide layer, and an aluminum oxide layer.

The first gate layer GTL1 may be located on the first gate insulating film GI1. The first gate layer GTL1 may include a first fan-out line FOL1, a first lead line LDL1, the gate electrode GE of the transistor TFT, and a first capacitor electrode CE1 of a first capacitor C1. The first gate layer GTL1 may be a single-layer film or multilayer film formed of Mo, Al, Cr, Au, Ti, Ni, Nd, Cu, or an alloy thereof.

The first fan-out line FOL1 may be connected to a pad unit PAD, which penetrates the first through third passivation layers PAS1 through PAS3, the interlayer insulating film ILD, and the second gate insulating film GI2. As the first fan-out line FOL1 extends from the pad unit PAD to the display area DA, the size of the non-display area NDA can be reduced. The first fan-out line FOL1 may be electrically connected to the data lines, the clock lines, or the voltage lines in the display area DA. The first fan-out line FOL1 may provide voltages or signals from the flexible film FPCB to the data lines, the clock lines, or the voltage lines.

The first lead line LDL1 may be electrically connected to the flexible film FPCB through the side connecting line SCL, which is located on a side of the display device 10, and to the second lead line LDL2, which is located at the bottom of the display device 10. The first lead line LDL1 may provide voltages or signals from the flexible film FPCB to the pad unit PAD and the first fan-out line FOL1.

The second gate insulating film GI2 may be located on the first gate layer GTL1. The second gate insulating film GI2 may insulate the first and second gate layers GTL1 and GTL2. The second gate insulating film GI2 may include an inorganic film. For example, the second gate insulating film GI2 may include one of a silicon nitride layer, a silicon oxynitride layer, a silicon oxide layer, a titanium oxide layer, and an aluminum oxide layer.

The second gate layer GTL2 may be located on the second gate insulating film GI2. The second gate layer GTL2 may include a second capacitor electrode CE2 of the first capacitor C1. The second gate layer GTL2 may be a single-layer film or multilayer film formed of Mo, Al, Cr, Au, Ti, Ni, Nd, Cu, or an alloy thereof.

The interlayer insulating film ILD may be located on the second gate layer GTL2. The interlayer insulating film ILD may insulate the first source metal layer SDL1 and the second gate layer GTL2. The interlayer insulating film ILD may include an inorganic film. For example, the interlayer insulating film ILD may include one of a silicon nitride layer, a silicon oxynitride layer, a silicon oxide layer, a titanium oxide layer, and an aluminum oxide layer.

The first source metal layer SDL1 may be located on the interlayer insulating film ILD. The first source metal layer SDL1 may include a connecting electrode CCE. The connecting electrode CCE may be connected to an anode connecting line ACL, which penetrates the first passivation layer PAS1 and the first via layer VIA1. The connecting electrode CCE may be connected to the drain electrode DE of the transistor TFT through the interlayer insulating film ILD, the second gate insulating film GI2, and the first gate insulating film GI1. Thus, the connecting electrode CCE may electrically connect the anode connecting line ACL and the drain electrode DE. The first source metal layer SDL1 may be a single-layer film or multilayer film formed of Mo, Al, Cr, Au, Ti, Ni, Nd, Cu, or an alloy thereof.

The first via layer VIA1 may be located on the first source metal layer SDL1. The first via layer VIA1 may planarize the top of the first source metal layer SDL1. The first via layer VIA1 may include an organic film formed of an acrylic resin, an epoxy resin, a phenolic resin, a polyamide resin, or a polyimide resin.

The first passivation layer PAS1 may be located on the first via layer VIA1, and may protect the first source metal layer SDL1. The first passivation layer PAS1 may include an inorganic film. For example, the first passivation layer PAS1 may include one of a silicon nitride layer, a silicon oxynitride layer, a silicon oxide layer, a titanium oxide layer, and an aluminum oxide layer.

The second source metal layer SDL2 may be located on the first via layer VIA1. The second source metal layer SDL2 may include the anode connecting line ACL. The anode connecting line ACL may be connected to an anode connecting electrode ACE, which penetrates the second passivation layer PAS2 and the second via layer VIA2. The anode connecting line ACL may be connected to the connecting electrode CCE, and may penetrate the first passivation layer PAS1 and the first via layer VIA1. Thus, the anode connecting line ACL may electrically connect the anode connecting electrode ACE and the connecting electrode CCE. The second source metal layer SDL2 may be a single-layer film or multilayer film formed of Mo, Al, Cr, Au, Ti, Ni, Nd, Cu, or an alloy thereof.

The second via layer VIA2 may be located on the second source metal layer SDL2. The second via layer VIA2 may planarize the top of the second source metal layer SDL2. The second via layer VIA2 may include an organic film formed of an acrylic resin, an epoxy resin, a phenolic resin, a polyamide resin, or a polyimide resin.

The second passivation layer PAS2 may be located on the second via layer VIA2, and may protect the second source metal layer SDL2. The second passivation layer PAS2 may include an inorganic film. For example, the second passivation layer PAS2 may include one of a silicon nitride layer, a silicon oxynitride layer, a silicon oxide layer, a titanium oxide layer, and an aluminum oxide layer.

The third source metal layer SDL3 may be located on the second via layer VIA2. The third source metal layer SDL3 may include the anode connecting electrode ACE. The anode connecting electrode ACE may be connected to a first pixel electrode AND1, which penetrates the third passivation layer PAS3 and the third via layer VIA3. The anode connecting electrode ACE may be connected to the anode connecting line ACL while passing through the second passivation layer PAS2 and the second via layer VIA2. Thus, the anode connecting electrode ACE may electrically connect the first pixel electrode AND1 and the anode connecting line ACL. The third source metal layer SDL3 may be a single-layer film or multilayer film formed of Mo, Al, Cr, Au, Ti, Ni, Nd, Cu, or an alloy thereof.

The third via layer VIA3 may be located on the third source metal layer SDL3. The third via layer VIA3 may planarize the top of the third source metal layer SDL3. The third via layer VIA3 may include an organic film formed of an acrylic resin, an epoxy resin, a phenolic resin, a polyamide resin, or a polyimide resin.

The third passivation layer PAS3 may be located on the third via layer VIA3, and may protect the third source metal layer SDL3. The third passivation layer PAS3 may include an inorganic film. For example, the third passivation layer PAS3 may include one of a silicon nitride layer, a silicon oxynitride layer, a silicon oxide layer, a titanium oxide layer, and an aluminum oxide layer.

The fourth source metal layer SDL4 may be located on the third passivation layer PAS3. The fourth source metal layer SDL4 may include the first pixel electrode AND1. The first pixel electrode AND1 may be connected to the anode connecting electrode ACE while passing through the third passivation layer PAS3 and the third via layer VIA3. The fourth source metal layer SDL4 may be a single-layer film or multilayer film formed of Mo, Al, Cr, Au, Ti, Ni, Nd, Cu, or an alloy thereof.

The anode layer ANDL may be located on the fourth source metal layer SDL4. The anode layer ANDL may include a second pixel electrode AND2. The anode layer ANDL may include a transparent conductive material, such as ITO, IZO, or ITZO.

The pad unit PAD may be located on the third passivation layer PAS3 in the non-display area NDA. The pad unit PAD may be connected between the first lead line LDL1 and the first fan-out line FOL1. The pad unit PAD may be electrically connected to the flexible film FPCB through the first lead line LDL1, the side connecting line SCL, and the second lead line LDL2. The pad unit PAD may include first and second pad electrodes PAD1 and PAD2. The first pad electrode PAD1 and the first pixel electrode AND1 may be formed of the same material by the same process. The first pad electrode PAD1 may be connected to the first fan-out line FOL1 while passing through the first through third passivation layers PAS1 through PAS3, the interlayer insulating film ILD, and the second gate insulating film GI2. The second pad electrode PAD2 may be located on the first pad electrode PAD1. The second pad electrode PAD2 and the second pixel electrode AND2 may be formed of the same material by the same process.

The fourth via layer VIA4 may be located on part of the third passivation layer PAS3 at an area where the pixel electrode AND is not formed. The fourth via layer VIA4 may planarize the top of the third passivation layer PAS3.

The fourth passivation layer PAS4 may be located on the fourth via layer VIA4, on the edges of the pixel electrode AND, and on the edges of the pad unit PAD. The fourth passivation layer PAS4 may include an inorganic film. For example, the fourth passivation layer PAS4 may include one of a silicon nitride layer, a silicon oxynitride layer, a silicon oxide layer, a titanium oxide layer, and an aluminum oxide layer. The fourth passivation layer PAS4 may not cover, but instead may expose, part of the top surface of a pixel electrode AND. The fourth passivation layer PAS4 may not cover, but instead may expose, part of the top surface of the pad unit PAD.

The light-emitting element ED may be located on part of the pixel electrode AND that is not covered by the fourth passivation layer PAS4. A contact electrode CAND may be located between the light-emitting element ED and the pixel electrode AND to electrically connect the light-emitting element ED and the pixel electrode AND. The pixel electrode AND may receive a driving current from the pixel circuit, and the light-emitting element ED may emit light of a corresponding luminance based on the magnitude of the driving current and the duration for which the driving current flows. The light-emitting element ED may be an inorganic LED. The light-emitting element ED may include a first semiconductor layer, an electronic blocking layer, an active layer, a superlattice layer, and a second semiconductor layer, which are sequentially stacked.

The first semiconductor layer may be located on the contact electrode CAND. The first semiconductor layer may be doped with a dopant of a first conductivity type, such as magnesium (Mg), zinc (Zn), calcium (Ca), selenium (Se), or barium (Ba). For example, the first semiconductor layer may be p-GaN doped with Mg, which is a p-type dopant.

The electron blocking layer may be located on the first semiconductor layer. The electron blocking layer may be a layer for suppressing or preventing an excessive number of electrons flowing into the active layer. For example, the electron blocking layer may be p-AlGaN doped with Mg, which is a p-type dopant. The electron blocking layer may be omitted in some embodiments.

The active layer may be located on the electron blocking layer. As electron-hole pairs combine in accordance with electric signals applied through the first and second semiconductor layers, the active layer may emit light. For example, the active layer may include a material of a single- or multi-quantum well structure. In a case where the active layer includes a material of the multi-quantum well structure, the active layer may have a structure in which a plurality of well layers and a plurality of barrier layers are alternately stacked.

In another example, the active layer may have a structure where a semiconductor material with a large bandgap energy and a semiconductor material with a small bandgap energy are alternately stacked or may include group-III to -V semiconductor materials depending on the wavelength range of light emitted by the active layer.

In a case where the active layer includes InGaN, the color of light to be emitted by the active layer may vary depending on the indium (In) content of the active layer. For example, as the In content of the active layer increases, the wavelength range of light emitted by the active layer may be switched to a red wavelength range, and as the In content of the active layer decreases, the wavelength of light emitted by the active layer may be switched to a blue wavelength range. For example, the In content of a light-emitting element ED of a third pixel SP3 may be about 15%, the In content of a light-emitting element ED of a second pixel SP2 may be about 25%, and the In content of a light-emitting element ED of a first pixel SP1 may be about 35% or greater. That is, the light-emitting elements ED of the first through third pixels SP1 through SP3 may be made to emit first-color light, second-color light, and third-color light, respectively, by controlling the In content of the active layer.

The superlattice layer may be located on the active layer. The superlattice layer may be a layer for alleviating the stress between the second semiconductor layer and the active layer. For example, the superlattice layer may be formed of InGaN or GaN. The superlattice layer may be omitted in some embodiments.

The second semiconductor layer may be located on the superlattice layer. The second semiconductor layer may be doped with a dopant of a second conductivity type, such as silicon (Si), germanium (Ge), or tin (Sn). For example, the second semiconductor layer may be n-GaN doped with Si, which is an n-type dopant.

The fifth passivation layer PAS5 may be located on the bottom surface of the substrate SUB, and may planarize the bottom of the substrate SUB. The fifth passivation layer PAS5 may include an inorganic film. For example, the fifth passivation layer PAS5 may include one of a silicon nitride layer, a silicon oxynitride layer, a silicon oxide layer, a titanium oxide layer, and an aluminum oxide layer.

The contact electrode CTE may be located on a first surface of, or the bottom surface of, the fifth passivation layer PAS5. The contact electrode CTE may provide voltages or signals from the flexible film FPCB to the side connecting line SCL through the second lead line LDL2. The contact electrode CTE may be electrically connected to the flexible film FPCB through a bonding film ACF.

The contact electrode CTE may include first and second contact electrodes CTE1 and CTE2. The first contact electrode CTE1 may be located on the first surface, or the bottom surface, of the fifth passivation layer PAS5. The first contact electrode CTE1 may be a single-layer film or multilayer film formed of Mo, Al, Cr, Au, Ti, Ni, Nd, Cu, or an alloy thereof. The second contact electrode CTE2 may be located on a first surface of, or a bottom surface of, the first contact electrode CTE1. The second contact electrode CTE2 may include a transparent conductive material, such as ITO, IZO, or ITZO.

The second lead line LDL2 may be located on the first surface of, or the bottom surface of, the fifth passivation layer PAS5. The second lead line LDL2 may extend from the flexible film FPCB in the display area DA to the edge of the non-display area NDA. The second lead line LDL2 and the first contact electrode CTE1 may be formed of the same material in the same layer. The second lead line LDL2 may provide voltages or signals from the contact electrode CTE to the side connecting line SCL.

The side connecting line SCL may be located on a side of the display device 10. A first end of the side connecting line SCL may be connected to a side of the second lead line LDL2, and a second end of the side connecting line SCL may be connected to a side of the first lead line LDL1. The side connecting line SCL may electrically connect the first and second lead lines LDL1 and LDL2. The side connecting line SCL may pass by the fifth passivation layer PAS5, the substrate SUB, the buffer layer BF, and sides of the first and second gate insulating films GI1 and GI2.

The fifth via layer VIA5 may cover the second lead line LDL2 and may expose the bottom surface of the contact electrode CTE. The fifth via layer VIA5 may planarize the bottom of the substrate SUB. The fifth via layer VIA5 may include an organic film formed of an acrylic resin, an epoxy resin, a phenolic resin, a polyamide resin, or a polyimide resin.

The sixth passivation layer PAS6 may be located on a first surface, or the bottom surface, of the fifth via layer VIA5, and may protect the contact electrode CTE and the second lead line LDL2. The sixth passivation layer PAS6 may include an inorganic film. For example, the sixth passivation layer PAS6 may include one of a silicon nitride layer, a silicon oxynitride layer, a silicon oxide layer, a titanium oxide layer, and an aluminum oxide layer.

The flexible film FPCB may be located on a first surface, or a bottom surface, of the sixth passivation layer PAS6. The flexible film FPCB may be attached to the bottom surface of the sixth passivation layer PAS6 via an adhesive member. The flexible film FPCB may provide voltages or signals to the first lead line LDL1 and the first fan-out line FOL1, which are located above the substrate SUB, through the contact electrode CTE, the second lead line LDL2, and the side connecting line SCL. The flexible film FPCB may allow one of the display drivers DIC to be mounted at the bottom of the substrate SUB. The flexible film FPCB may transmit signals from one of the display drivers DIC to the unit pixels UP.

The bonding film ACF may attach the flexible film FPCB to the bottom surface of the contact electrode CTE. For example, the bonding film ACF may include an anisotropic conductive film. In a case where the bonding film ACF includes an anisotropic conductive film, the bonding film ACF may have conductivity in a region where the contact electrode CTE and the flexible film FPCB are in contact with each other, and may electrically connect the flexible film FPCB to the contact electrode CTE.

As the display device 10 includes the flexible film FPCB, which is located below the substrate SUB, the first fan-out line FOL1, which is located above the substrate SUB, and includes the contact electrode CTE, the second lead line LDL2, the side connecting line SCL, and the first lead line LDL1, which electrically connect the flexible film FPCB and the first fan-out line FOL1, the size of the non-display area NDA can be reduced or minimized.

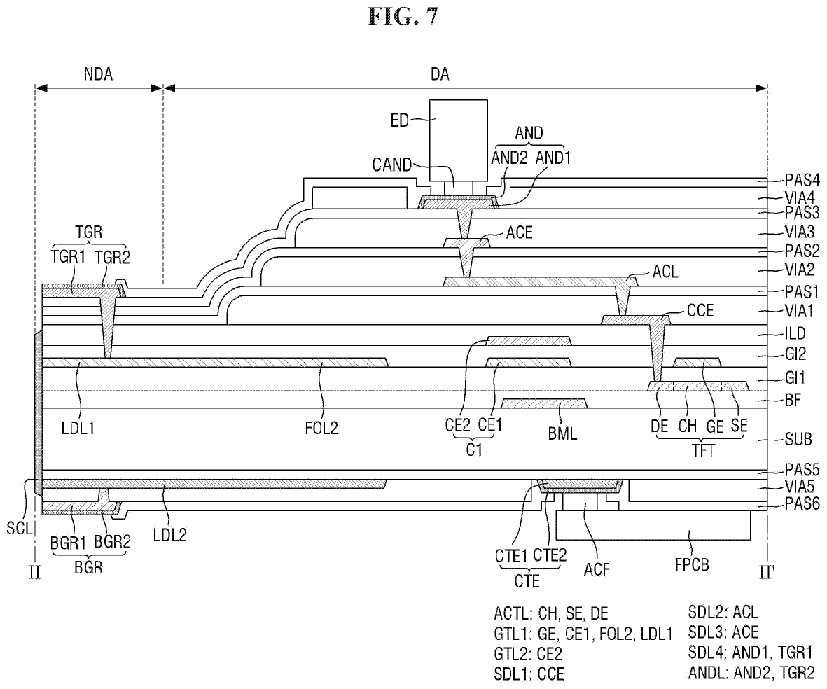

FIG. 7 is a cross-sectional view taken along the line II-II′ of FIG. 2. In FIGS. 6 and 7, like reference numerals denote like elements, and thus, detailed descriptions thereof will be omitted.

Referring to FIG. 7, the display device 10 may include a second fan-out line FOL2, a first lead line LDL1, a top antistatic layer TGR, a side connecting line SCL, a second lead line LDL2, and a bottom antistatic layer BGR.

The second fan-out line FOL2 may be connected to the top antistatic layer TGR, which penetrates the first through third passivation layers PAS1 through PAS3, the interlayer insulating film ILD, and the second gate insulating film GI2. As the second fan-out line FOL2 extends from the non-display area NDA to the display area DA, the size of the non-display area NDA can be reduced. The second fan-out line FOL2 may be electrically connected to a low-potential electrode or a common voltage line in the display area DA. The second fan-out line FOL2 may provide a low-potential voltage or a common voltage from the flexible film FPCB to the low-potential electrode or the common voltage line. The low-potential electrode or the common voltage line may be located in at least one of the first through third source metal layers SDL1 through SDL3, but the present disclosure is not limited thereto. The second fan-out line FOL2 can suitably discharge static electricity, which may be introduced during the cutting or grinding of the display device 10, through the low-potential electrode or the common voltage line.

The first lead line LDL1 may be electrically connected to the flexible film FPCB through the side connecting line SCL, which is located on a side of the display device 10, and the second lead line LDL2, which is located at the bottom of the display device 10. The first lead line LDL1 may provide voltages or signals from the flexible film FPCB to the second fan-out line FOL2.

The top antistatic layer TGR may be located along the edge of the top surface of the display device 10 or along the edge of the top surface of the substrate SUB to surround the display area DA. The top antistatic layer TGR may include first and second top antistatic layers TGR1 and TGR2. The first top antistatic layer TGR1 may be located in the fourth source metal layer SDL4. The first top antistatic layer TGR1 and a first pixel electrode AND1 may be formed of the same material by the same process. The first top antistatic layer TGR1 may be connected to the second fan-out line FOL2 while passing through the first through third passivation layers PAS1 through PAS3, the interlayer insulating film ILD, and the second gate insulating film GI2. The second top antistatic layer TGR2 may be located on the first top antistatic layer TGR1. The second top antistatic layer TGR2 may be located in the anode layer ANDL. The second top antistatic layer TGR2 and a second pixel electrode AND2 may be formed of the same material by the same process. One edge of the second top antistatic layer TGR2 may be covered by the fourth passivation layer PAS4, but the top surface of the second top antistatic layer TGR2 might not be covered, but instead may be exposed by the fourth passivation layer PAS4.

The top antistatic layer TGR may be a guard ring capable of reducing or preventing static electricity, but the present disclosure is not limited thereto. The top antistatic layer TGR may be electrically connected to a low-potential electrode or a common voltage line, and may thus be able to suitably discharge static electricity. As the top antistatic layer TGR is located along the edge of the top surface of the display device 10, static electricity, which may be introduced during the cutting or grinding of the display device 10, can be discharged and can thus be prevented from being introduced into the display area DA. The top antistatic layer TGR can suitably discharge static electricity that may be introduced from above the display device 10.

For example, the top antistatic layer TGR may include a transparent conductive material, such as ITO, IZO, or ITZO. In another example, the top antistatic layer TGR may have a stack structure, such as ITO/Ag/ITO, ITO/Ag/IZO, or ITO/Ag/ITZO/IZO. In yet another example, the top antistatic layer TGR may include at least one of Mo, Al, Cr, Au, Ti, Ni, Nd, and Cu.

The side connecting line SCL may be located on the side of the display device 10. A first end of the side connecting line SCL may be connected to a side of the second lead line LDL2, and a second end of the side connecting line SCL may be connected to a side of the first lead line LDL1. The side connecting line SCL may electrically connect the first and second lead lines LDL1 and LDL2. The side connecting line SCL may pass by the fifth passivation layer PAS5, the substrate SUB, the buffer layer BF, and the sides of the first and second gate insulating films GI1 and GI2.

The second lead line LDL2 may be located on the first surface, or the bottom surface, of the fifth passivation layer PAS5. The second lead line LDL2 may extend from the flexible film FPCB in the display area DA to the edge of the non-display area NDA. The second lead line LDL2 and the first contact electrode CTE1 may be formed of the same material in the same layer. The second lead line LDL2 may provide voltages or signals from the contact electrode CTE to the side connecting line SCL.

The bottom antistatic layer BGR may be located on the edge of the bottom surface of the display device 10 or along the edge of the bottom surface of the substrate SUB. The bottom antistatic layer BGR may include first and second bottom antistatic layers BGR1 and BGR2. The first bottom antistatic layer BGR1 may be located on the first surface, or the bottom surface, of the fifth via layer VIA5. The first bottom antistatic layer BGR1 may be connected to the second lead line LDL2 while passing through the fifth via layer VIA5. The second bottom antistatic layer BGR2 may be located on a first surface, or the bottom surface, of the first bottom antistatic layer BGR1. The second bottom antistatic layer BGR2 and the second contact electrode CTE2 may be formed of the same material. One edge of the second bottom antistatic layer BGR2 may be covered by the sixth passivation layer PAS6, but the top surface of the second bottom antistatic layer BGR2 may not be covered, but instead may be exposed by the sixth passivation layer PAS6.

The bottom antistatic layer BGR may be a guard ring capable of reducing or preventing static electricity, but the present disclosure is not limited thereto. The bottom antistatic layer BGR may be electrically connected to the low-potential electrode or the common voltage line through the second lead line LDL2, the side connecting line SCL, the first lead line LDL1, and the second fan-out line FOL2, and may thus be able to suitably discharge static electricity. As the bottom antistatic layer BGR is located along the edge of the bottom surface of the display device 10, static electricity, which may be introduced during the cutting or grinding of the display device 10, can be discharged, and can thus be prevented from being introduced into the display area DA. The bottom antistatic layer BGR can suitably discharge static electricity that may be introduced from below the display device 10.

For example, the bottom antistatic layer BGR may include a transparent conductive material, such as ITO, IZO, or ITZO. In another example, the bottom antistatic layer BGR may have a stack structure, such as ITO/Ag/ITO, ITO/Ag/IZO, or ITO/Ag/ITZO/IZO. In yet another example, the bottom antistatic layer BGR may include at least one of Mo, Al, Cr, Au, Ti, Ni, Nd, and Cu.

As the display device 10 includes the flexible film FPCB and a display driver DIC at the bottom thereof, the size of the non-display area NDA can be reduced or minimized, and the pixel pitch between the display device 10 and other neighboring display devices 10 can be designed to be the same as the pixel pitch within the display device 10. As the display device 10 includes the top antistatic layer TGR, static electricity that may be introduced from above the display device 10 can be discharged so that damage to the TFT layer and the light-emitting element layer can be reduced or prevented. As the display device 10 includes the bottom antistatic layer BGR, static electricity that may be introduced from below the display device 10 can be discharged so that damage to the second lead line LDL2, the flexible film FPCB, and the display driver DIC can be reduced or prevented.

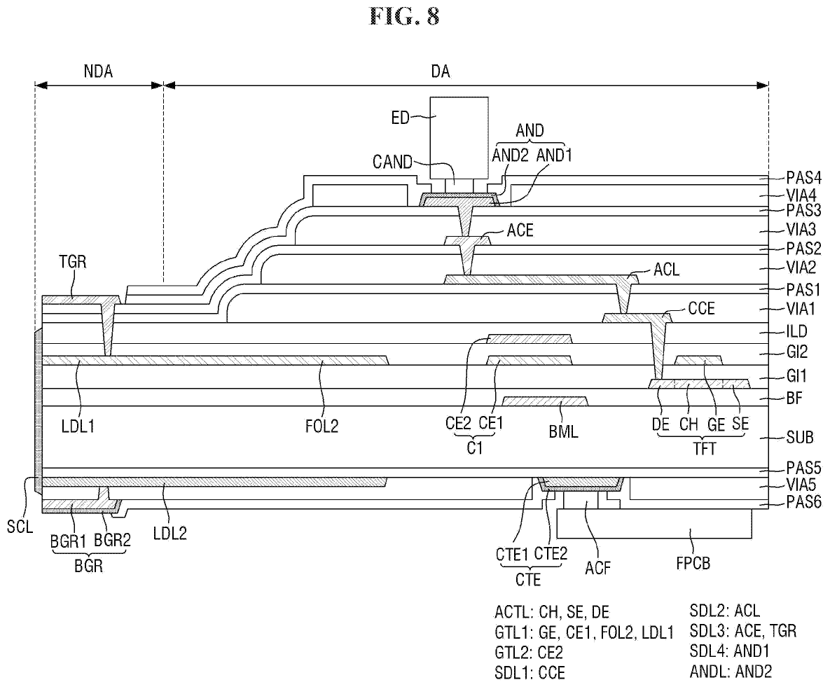

FIG. 8 is a cross-sectional view taken along the line II-II′ of FIG. 2. The one or more embodiments corresponding to FIG. 8 differs from the one or more embodiments corresponding to FIG. 7 in the configuration of the top antistatic layer TGR. In FIGS. 7 and 8, like reference numerals denote like elements, and thus, detailed descriptions thereof will be omitted.

Referring to FIG. 8, the top antistatic layer TGR may be located along the edge of the top surface of the display device 10 or along the edge of the top surface of the substrate SUB to surround the display area DA. The top antistatic layer TGR may be located in the third source metal layer SDL3. The top antistatic layer TGR and the anode connecting electrode ACE may be formed by the same material by the same process. The top antistatic layer TGR may be connected to the second fan-out line FOL2 through the first and second passivation layers PAS1 and PAS2, the interlayer insulating film ILD, and the second gate insulating film GI2. The top surface of the top antistatic layer TGR may not be covered, but instead may be exposed by the third and fourth passivation layers PAS3 and PAS4.

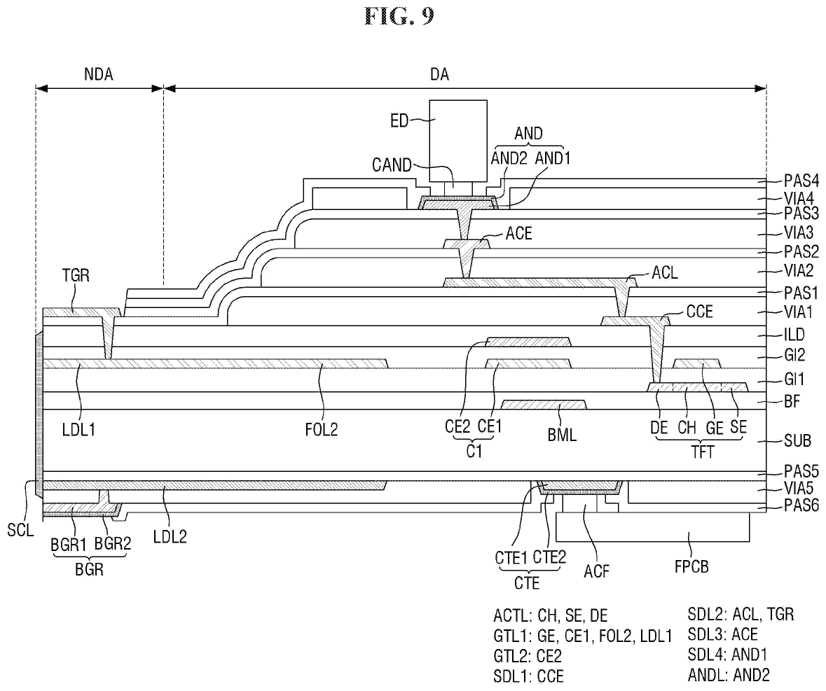

FIG. 9 is a cross-sectional view taken along the line II-II′ of FIG. 2. The one or more embodiments corresponding to FIG. 9 differs from the one or more embodiments corresponding to FIG. 7 in the configuration of the top antistatic layer TGR. In FIGS. 7 and 9, like reference numerals denote like elements, and thus, detailed descriptions thereof will be omitted.

Referring to FIG. 9, the top antistatic layer TGR may be located along the edge of the top surface of the display device 10 or along the edge of the top surface of the substrate SUB to surround the display area DA. The top antistatic layer TGR may be located in the second source metal layer SDL2. The top antistatic layer TGR and the anode connecting line ACL may be formed of the same material by the same process. The top antistatic layer TGR may be connected to the second fan-out line FOL2 through the first passivation layer PAS1, the interlayer insulating film ILD, and the second gate insulating film GI2. The top surface of the top antistatic layer TGR may not be covered, but instead may be exposed by the second through fourth passivation layers PAS2 through PAS4.

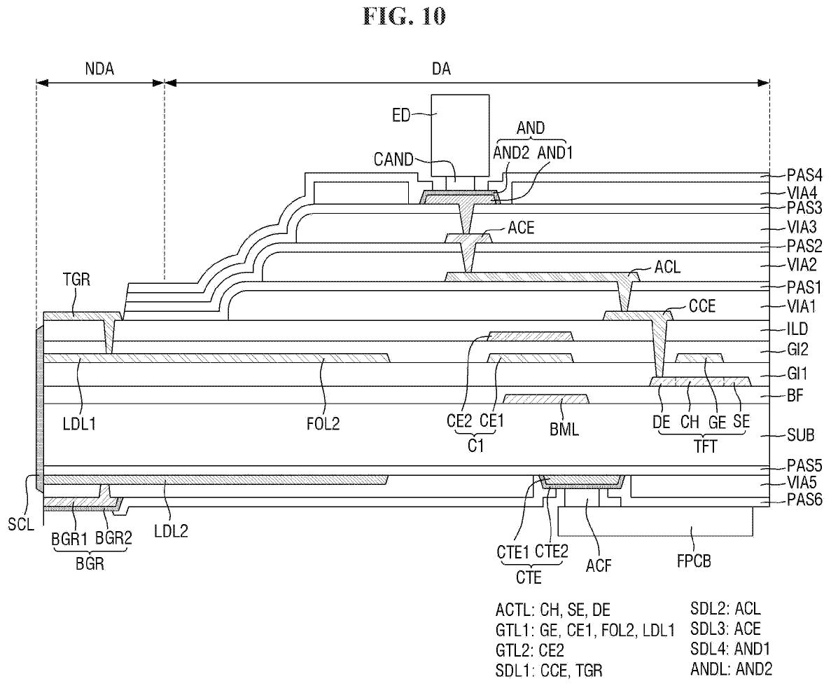

FIG. 10 is a cross-sectional view taken along the line II-II′ of FIG. 2. The one or more embodiments corresponding to FIG. 10 differs from the one or more embodiments corresponding to FIG. 7 in the configuration of the top antistatic layer TGR. In FIGS. 7 and 10, like reference numerals denote like elements, and thus, detailed descriptions thereof will be omitted.

Referring to FIG. 10, the top antistatic layer TGR may be located along the edge of the top surface of the display device 10 or along the edge of the top surface of the substrate SUB to surround the display area DA. The top antistatic layer TGR may be located in the first source metal layer SDL1. The top antistatic layer TGR and the connecting electrode CCE may be formed of the same material by the same process. The top antistatic layer TGR may be connected to the second fan-out line FOL2 through the interlayer insulating film ILD and the second gate insulating film GI2. The top surface of the top antistatic layer TGR may not be covered, but instead may be exposed by the first through fourth passivation layers PAS1 through PAS4.

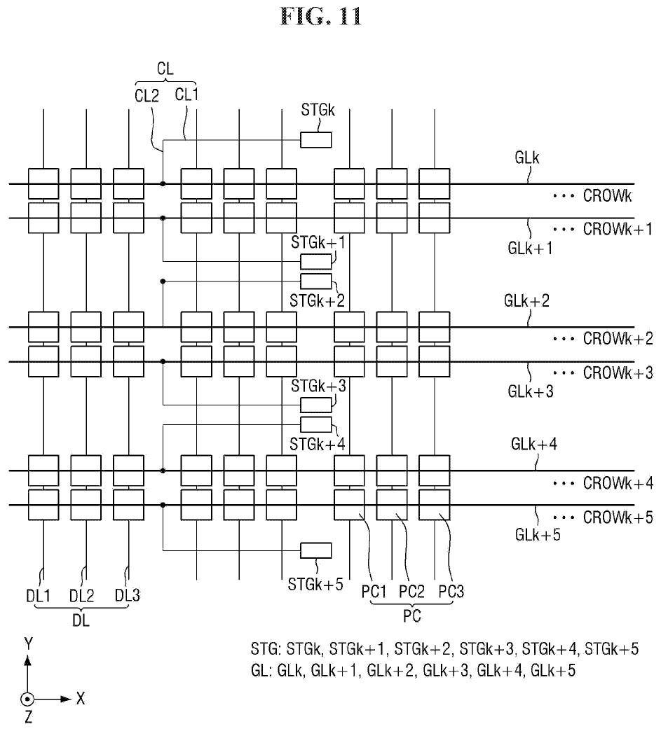

FIG. 11 illustrates how stages and gate lines are connected in the display device of FIG. 2.

Referring to FIG. 11, the display area DA may include pixel circuits PC, stages STG, and gate lines GL.

The pixel circuits PC may be connected to data lines DL and the gate lines GL. The pixel circuits PC may include first pixel circuits PC1, second pixel circuits PC2, and third pixel circuits PC3. The first pixel circuits PC1 may receive data voltages from first data lines DL1, and may provide driving currents to first pixels SP1. The second pixel circuits PC2 may receive data voltages from second data lines DL2, and may provide driving currents to second pixels SP2. The third pixel circuits PC3 may receive data voltages from third data lines DL3, and may provide driving currents to third pixels SP3. The pixel circuits PC may be arranged in multiple rows.

The stages STG may be located in the display area DA. The stages STG may receive clock signals from clock lines in the display area DA, and may receive voltage signals from voltage lines in the display area DA. The stages STG may generate gate signals, and may provide the gate signals to the gate lines GL. The stages STG may include k-th through (k+5)-th stages STGk through STGk+5.

The k-th stage STGk may be located on the upper side of a k-th circuit row CROWk. The k-th stage STGk may provide a gate signal to a k-th gate line GLk, which is connected to pixel circuits PC in the k-th circuit row CROWk. The k-th stage STGk may be connected to the k-th gate line GLk through a connecting line CL. The k-th stage STGk may be connected to the k-th gate line GLk through a first connecting line CL1, which extends in a first direction (or an X-axis direction), and through a second connecting line CL2, which extends in a second direction (or a Y-axis direction).

The (k+1)-th and (k+2)-th stages STGk+1 and STGk+2 may be located between (k+1)-th and (k+2)-th circuit rows CROWk+1 and CROWk+2. The (k+1)-th stage STGk+1 may be located on the lower side of the (k+1)-th circuit row CROWk+1. The (k+1)-th stage STGk+1 may provide a gate signal to a (k+1)-th gate line GLk+1, which is connected to pixel circuits PC in the (k+1)-th circuit row CROWk+1. The (k+1)-th stage STGk+1 may be connected to the (k+1)-th gate line GLk+1 through a corresponding connecting line CL.

The (k+2)-th stage STGk+2 may be located on the upper side of the (k+2)-th circuit row CROWk+2. The (k+2)-th stage STGk+2 may provide a gate signal to a (k+2)-th gate line GLk+2, which is connected to pixel circuits PC in the (k+2)-th circuit row CROWk+2. The (k+2)-th stage STGk+2 may be connected to the (k+2)-th gate line GLk+2 through a corresponding connecting line CL.

The (k+3)-th and (k+4)-th stages STGk+3 and STGk+4 may be located between (k+3)-th and (k+4)-th circuit rows CROWk+3 and CROWk+4. The (k+3)-th stage STGk+3 may be located on the lower side of the (k+3)-th circuit row CROWk+3. The (k+3)-th stage STGk+3 may provide a gate signal to a (k+3)-th gate line GLk+3, which is connected to pixel circuits PC in the (k+3)-th circuit row CROWk+3. The (k+3)-th stage STGk+3 may be connected to the (k+3)-th gate line GLk+3 through a corresponding connecting line CL.

The (k+4)-th stage STGk+4 may be located on the upper side of the (k+4)-th circuit row CROWk+4. The (k+4)-th stage STGk+4 may provide a gate signal to a (k+4)-th gate line GLk+4, which is connected to pixel circuits PC in the (k+4)-th circuit row CROWk+4. The (k+4)-th stage STGk+4 may be connected to the (k+4)-th gate line GLk+4 through a corresponding connecting line CL.

The (k+5)-th stage STGk+5 may be located on the lower side of a (k+5)-th circuit row CROWk+5. The (k+5)-th stage STGk+5 may provide a gate signal to a (k+5)-th gate line GLk+5, which is connected to pixel circuits PC in the (k+5)-th circuit row CROWk+5. The (k+5)-th stage STGk+5 may be connected to the (k+5)-th gate line GLk+5 through a corresponding connecting line CL.

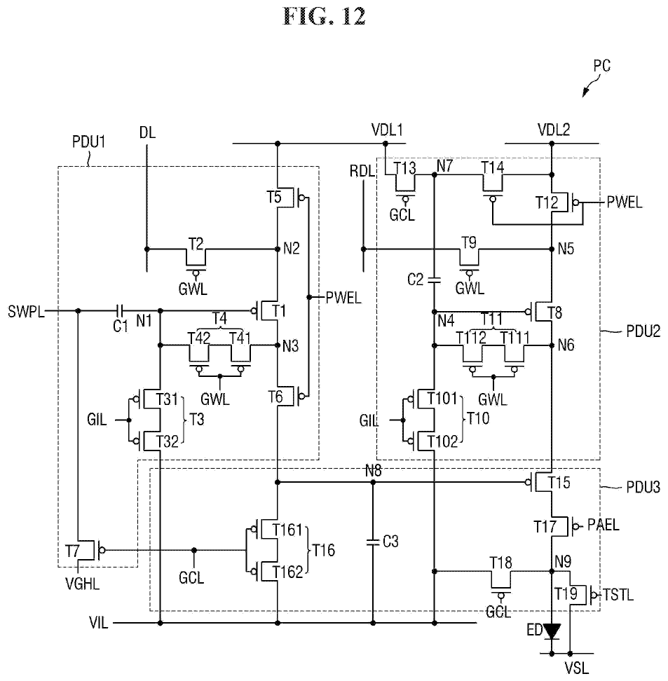

FIG. 12 is a circuit diagram of a pixel of the display device of FIG. 2.

Referring to FIG. 12, a pixel SP may include a pixel circuit PC and a light-emitting element ED. The pixel circuit PC may include first through third pixel drivers PDU1 through PDU3. The first pixel driver PDU1 may include first through seventh transistors T1 through T7 and a first capacitor C1.

The first transistor T1 may control a control current, which is provided to an eighth node N8 of the third pixel driver PDU3, based on the voltage of a first node N1, which is the gate electrode of the first transistor T1. The second transistor T2 may be turned on by a scan write signal from a scan write line GWL to provide a data voltage from a data line DL to a second node N2, which is the first electrode of the first transistor T1. The third transistor T3 may be turned on based on a scan initialization signal from a scan initialization line GIL to discharge the first node N1 to the initialization voltage VINT. For example, the third transistor T3 may include (3−1)-th and (3−2)-th transistors T31 and T32, which are connected in series. The fourth transistor T4 may be turned on based on the scan write signal from the scan write line GWL to electrically connect the first node N1 and a third node N3, which is the second electrode of the first transistor T1. For example, the fourth transistor T4 may include (4−1)-th and (4−2)-th transistors T41 and T42, which are connected in series.

The fifth transistor T5 may be turned on based on a PWM emission signal from a PWM emission line PWEL to electrically connect a first power supply line VDL1 and the second node N2. The sixth transistor T6 may be turned on based on the PWM emission signal from the PWM emission line PWEL to electrically connect the third node N3 and the eighth node N8 of the third pixel driver PDU3. The seventh transistor T7 may be turned on based on a scan control signal from a scan control line GCL to supply the gate-off voltage VGH from the gate-high voltage line VGHL to the second capacitor electrode of the first capacitor C1, which is connected to the sweep line SWPL. The first capacitor C1 may be connected between the first node N1 and the sweep line SWPL.

The second pixel driver PDU2 may include eighth through fourteenth transistors T8 through T14 and a second capacitor C2.

The eighth transistor T8 may control a driving current that flows in the light-emitting element ED, based on the voltage of a fourth node N4, which is the gate electrode of the eighth transistor T8. The ninth transistor T9 may be turned on based on the scan write signal from the scan write line GWL to supply a first pulse amplitude modulation (PAM) data voltage from a first PAM data line RDL to a fifth node N5, which is the first electrode of the eighth transistor T8. The tenth transistor T10 may be turned on based on the scan initialization signal from the scan initialization line GIL to discharge the fourth node N4 to the initialization voltage VINT. For example, the tenth transistor T10 may include (10−1)-th and (10−2)-th transistors T101 and T102, which are connected in series. The eleventh transistor T11 may be turned on based on the scan write signal from the scan write line GWL to electrically connect the fourth node N4 and a sixth node N6, which is the second electrode of the eighth transistor T8. For example, the eleventh transistor T11 may include (11−1)-th and (11−2)-th transistors T111 and T112, which are connected in series.

The twelfth transistor T12 may be turned on based on the PWM emission signal from the PWM emission line PWEL to electrically connect a second power supply line VDL2 and the fifth node N5. The thirteenth transistor T13 may be turned on based on the scan control signal from the scan control line GCL to electrically connect the first power supply line VDL1 and a seventh node N7, which is the second capacitor electrode of the second capacitor C2. The fourteenth transistor T14 may be turned on the PWM emission signal from the PWM emission line PWEL to electrically connect the second power supply line VDL2 and the seventh node N7. The second capacitor C2 may be connected between the fourth and seventh nodes N4 and N7.

The third pixel driver PDU3 may include fifteenth through nineteenth transistors T15 through T19 and a third capacitor C3.

The fifteenth transistor T15 may control the period for which the driving current flows, based on a control current received by the eighth node N8, which is the gate electrode of the fifteenth transistor T15. The sixteenth transistor T16 may be turned on based on the scan control signal from the scan control line GCL to discharge the eighth node N8 to the initialization voltage VINT. For example, the sixteenth transistor T16 may include (16−1)-th and (16−2)-th transistors T161 and T162, which are connected in series. The seventh transistor T17 may be turned on based on the

PAM emission signal from the PAM emission line PAEL to electrically connect the second electrode of the fifteenth transistor T15 and a ninth node N9, which is the first electrode of the light-emitting element ED. The eighteenth transistor T18 may be turned on based on the scan control signal from the scan control line GCL to discharge the ninth node N9 to as low as the initialization voltage VIL. The nineteenth transistor

T19 may be turned on based on a test signal from a test signal line TSTL to electrically connect the ninth node N9 and a third power supply line VSL. The third capacitor C3 may be connected between the eighth node N8 and an initialization voltage line VIL.

The light-emitting element ED may be connected between the ninth node N9 and the third power supply line VSL.

For example, one of the first and second electrodes of each of the first through nineteenth transistors T1 through T19 may be a source electrode, and the other electrode of each of the first through nineteenth transistors T1 through T19 may be a drain electrode. The first through nineteenth transistors T1 through T19 may be implemented as P-type metal-oxide semiconductor field-effect transistors (MOSFETs), but the present disclosure is not limited thereto. Alternatively, at least one of the first through nineteenth transistors T1 through T19 may be implemented as an N-type MOSFET.

The pixel SP of FIG. 12 may correspond to a first pixel SP1 connected to the first PAM data line RDL. Second and third pixels SP2 and SP3 may have the same circuitry configuration as a first pixel SP1 except that they are connected to second and third PAM data lines.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by those of ordinary skill in the art that various variations in form and details may be made therein without departing from the spirit and scope of the disclosure as defined by the following claims, with functional equivalents thereof to be included therein.

What is claimed is:

1. A display device comprising:
a substrate comprising a display area for displaying an image, and a non-display area around the display area;
fan-out lines above the substrate;
top antistatic layers along edges of a top surface above the substrate, and electrically connected to the fan-out lines;
lead lines below the substrate;
side connecting lines on sides of the substrate, and electrically connecting the fan-out lines and the lead lines; and
bottom antistatic layers along edges of a bottom surface below the substrate, and electrically connected to the lead lines.

2. The display device of claim 1, further comprising pixel electrodes in the display area, and configured to receive driving currents,
wherein the top antistatic layers and the pixel electrodes comprise a same material in a same layer.

3. The display device of claim 2, further comprising a passivation layer covering edges of the pixel electrodes, and covering edges of the top antistatic layers such that top surfaces of top antistatic layers are exposed by the passivation layer.

4. The display device of claim 2, wherein the top antistatic layers comprise at least one of indium tin oxide (ITO), indium zinc oxide (IZO), or indium tin zinc oxide (ITZO).

5. The display device of claim 1, further comprising pad units in the non-display area, and separated from the top antistatic layers in plan view.

6. The display device of claim 1, wherein some of the lead lines are separated from the bottom antistatic layers in plan view, and extend from the display area to edges of the non-display area.

7. The display device of claim 1, wherein the fan-out lines are electrically connected to a low-potential electrode or a common voltage line.

8. The display device of claim 1, further comprising:
contact electrodes below the substrate, and electrically connected to the lead lines; and
flexible films electrically connected to the contact electrodes,
wherein the bottom antistatic layers and the contact electrodes comprise a same material.

9. The display device of claim 1, wherein the side connecting lines are not in direct contact with the top antistatic layers or the bottom antistatic layers.

10. The display device of claim 1, further comprising:
pixels comprising at least one light-emitting element; and
antistatic circuits between the top antistatic layers and the pixels.

11. The display device of claim 1, further comprising:
transistors above the substrate;
connecting electrodes above, and electrically connected to, the transistors;
anode connecting lines above, and electrically connected to, the connecting electrodes;
anode connecting electrodes above, and electrically connected to, the anode connecting lines; and
pixel electrodes above, and electrically connected to, the anode connecting electrodes.

12. The display device of claim 11, wherein the top antistatic layers and the anode connecting electrodes comprise a same material in a same layer.

13. The display device of claim 11, wherein the top antistatic layers and the anode connecting lines comprise a same material in a same layer.

14. The display device of claim 11, wherein the top antistatic layers and the connecting electrodes comprise a same material in a same layer.

15. A display device comprising:
a substrate comprising a display area for displaying an image, and a non-display area around the display area;
fan-out lines above the substrate;
top antistatic layers along edges of a top surface above the substrate, and electrically connected to the fan-out lines;
side connecting lines on sides of the substrate, and electrically connecting the fan-out lines and lead lines; and
bottom antistatic layers along edges of a bottom surface below the substrate, and electrically connected to the fan-out lines,
wherein the side connecting lines are not in direct contact with the top antistatic layers or the bottom antistatic layers.

16. The display device of claim 15, further comprising:
flexible films below the substrate; and
lead lines electrically connected between the flexible films and the side connecting lines.

17. The display device of claim 16, wherein the bottom antistatic layers are electrically connected to the fan-out lines through the lead lines and the side connecting lines.

18. The display device of claim 15, further comprising pad units in the non-display area, and separated from the top antistatic layers in plan view.

19. The display device of claim 15, wherein some of the lead lines are separated from the bottom antistatic layers in plan view, and extend from the display area to edges of the non-display area.

20. A tiled display device comprising:
display devices comprising:
a substrate comprising a display area for displaying an image, and a non-display area around the display area;
fan-out lines above the substrate;
top antistatic layers along edges of a top surface above the substrate, and electrically connected to the fan-out lines;
lead lines below the substrate;
side connecting lines on sides of the substrate, and electrically connecting the fan-out lines and the lead lines; and
bottom antistatic layers along edges of a bottom surface below the substrate, and electrically connected to the lead lines; and
a bonding area between the display devices.
